(19) United States
(12) Patent Application Publication
(10) Pub. No.: US 2025/0011918 A1
(43) Pub. Date: Jan. 9, 2025

(54) AUTOMATED THIN FILM DEPOSITION SYSTEM AND THIN FILM DEPOSITION METHOD TO WHICH MACHINE LEARNING IS APPLIED

(71) Applicant: SEOUL NATIONAL UNIVERSITY R&DB FOUNDATION, Seoul (KR)

(72) Inventors: Gyu Chul Yi, Seoul (KR); Won Woo Suh, Seoul (KR)

(21) Appl. No.: 18/279,027

(22) PCT Filed: Feb. 23, 2023
(86) PCT No.: PCT/KR2023/002571

§ 371 Date: Aug. 25, 2023

(30) Foreign Application Priority Data
Oct. 5, 2022 (KR) 10-2022-0127403

(51) Int. Cl. C23C 14/54; C23C 14/50; C23C 14/58; C23C 16/458; C23C 16/46; C23C 16/52; C23C 16/56; C30B 25/16; G01N 21/21; G01N 23/20058; G01N 23/2251; G06N 20/00

(52) U.S. Cl. CPC C23C 14/547; C23C 14/50; C23C 14/541; C23C 14/5873; C23C 16/4586; C23C 16/46; C23C 16/52; C23C 16/56; C30B 25/16; G01N 21/211; G01N 23/20058; G01N 23/2251; G06N 20/00

(57) ABSTRACT

The present disclosure discloses an automated thin film deposition system comprises a substrate holder which is disposed in a chamber for depositing a thin film, and on which the thin film is to be deposited is placed, a temperature adjust device for controlling a temperature of the substrate placed on the substrate holder, a raw material supply device for supplying a raw material for deposition of the thin film to the substrate placed on the substrate holder, an analysis device for analyzing property of the thin film deposited on the substrate, a removal device configured to remove the thin film from the substrate, and a control device which is connected to the temperature adjust device, the raw material supply device, the analysis device, and the removal device.

### TECHNICAL FIELD

The present invention relates to a thin film deposition system/apparatus and a thin film deposition method, and more particularly, to a thin film deposition system/device and a thin film deposition method to which machine learning is applied.

### BACKGROUND ART

In order to manufacture high-quality thin films required for semiconductor processes, systematic and simultaneous monitoring of various variables, such as the amount and ratio of raw materials, process temperature, and deposition time and speed are required, and an optimization process for changing process parameters by evaluating the manufactured thin film using various analysis methods is required. However, this process is quite inefficient because it not only consumes a lot of cost and substances, but also requires a process in which researchers (developers) must continuously supply/load substances and substrates, analyze thin films, and adjust parameters.

On the other hand, as two-dimensional materials (2D materials) such as graphene, TMD (transition metal chalcogenide), and h-BN (hexagonal-boron nitride) have new and excellent properties that are not observed in general materials, and may play an important role in manufacturing flexible devices or optical devices, it has recently attracted a lot of attention in the field of semiconductor/electronic devices and optical devices. In order to manufacture devices having excellent performance or to observe new scientific phenomena, a technique for manufacturing a two-dimensional material with excellent crystallinity and high purity is required. Various methods may be used to produce a two-dimensional material with uniform and excellent crystallinity. Several raw materials may be changed into liquid, gas, beam, etc. and reacted in vacuum, and through these processes, a two-dimensional material may be synthesized and grown on a substrate. However, as mentioned above, there is a problem that the process of optimizing the process parameters related to the manufacture of such a two-dimensional material is quite inefficient and consumes a lot of cost and time.

Therefore, in solving the above inefficiency problem and optimizing the manufacturing conditions (process conditions) of a thin film such as a two-dimensional material, development of a control device and a process system capable of growing a thin film of high-quality unattended and automatically under optimal conditions is required.

### DISCLOSURE OF THE INVENTION

### Technical Problem

The technological object to be achieved by the present invention is to provide an automated thin film deposition system and thin film deposition method capable of easily growing a high-quality thin film in an automated manner by applying a machine learning method in optimizing the manufacturing conditions (process conditions) of a thin film such as a two-dimensional material.

The objects to be solved by the present invention is not limited to the objects mentioned above, and other objects not mentioned will be understood by those skilled in the art from the description below.

### Technical Solution

According to one embodiment of the present invention, there is provided an automated thin film deposition system to which machine learning is applied, comprising; a substrate holder which is disposed in a chamber for depositing a thin film, and on which a substrate on which the thin film is to be deposited is placed; a temperature adjust device for controlling a temperature of the substrate placed on the substrate holder; a raw material supply device for supplying a raw material for deposition of the thin film to the substrate placed on the substrate holder; an analysis device for analyzing property of the thin film deposited on the substrate; a removal device configured to remove the thin film from the substrate; and a control device which is connected to the temperature adjust device, the raw material supply device, the analysis device, and the removal device, and comprising a processor capable of processing data obtained from the analysis device and learning a correlation between a process parameter for depositing the thin film and property of the thin film through machine learning, wherein the control device is configured to remove the thin film from the substrate by using at least one of the removal device and the temperature adjust device when the property of the thin film analyzed by the analysis device is less than a given reference level, and to deposit a new thin film on the substrate by changing the process parameter.

The thin film may include a two-dimensional material.

The removal device may be configured to generate at least one of plasma, laser, ion beam, and etching gas, and to remove the thin film from the substrate disposed in the chamber using at least one of the plasma, laser, ion beam, and etching gas.

The raw material supply device may be provided in plurality.

The analysis device may include an analysis source generating unit generating an analysis source for analyzing the property of the thin film; and an analysis data acquisition unit for acquiring data corresponding to the property of the thin film.

The analysis source generating unit may be configured to generate at least one of an electron beam, an X-ray, and a laser as the analysis source, and the analysis data acquisition unit may be configured to include at least one of a fluorescent screen, a camera, and an X-ray detector.

The analysis device may be configured to analyze the property of the thin film by using at least one of scanning electron microscopy (SEM), transmission electron microscopy (TEM), reflection high-energy electron diffraction (RHEED), low-energy electron diffraction (LEED), ellipsometry, and X-ray diffraction (XRD).

The control device may be configured to terminate the deposition of the thin film when the property of the thin film analyzed by the analysis device is equal to or greater than the reference level.

The thin film deposition system may be configured to deposit a thin film by using any one of evaporation deposition, metal-organic chemical vapor deposition (MOCVD), molecular beam epitaxy (MBE), pulsed laser deposition (PLD), and sputtering deposition.

According to another embodiment of the present invention, there is provided an automated thin film deposition method to which machine learning is applied, and which comprises: depositing a thin film on a substrate disposed in a chamber for thin film deposition; analyzing property of the thin film in a state where the substrate is disposed in the chamber; determining whether the property of the thin film has reached a given reference level; removing the thin film from the substrate in a state where the substrate is disposed in the chamber when the property of the thin film is determined to be less than the reference level; and depositing a new thin film on the substrate under a changed process condition by changing a process parameter for thin film deposition using a machine learning method for learning a correlation between a process parameter for thin film deposition and property of the thin film.

The thin film may include a two-dimensional material.

The removing the thin film from the substrate may include at least any one of irradiating or supplying at least one of plasma, laser, ion beam, and etching gas to the thin film; and increasing a temperature of the substrate above a critical temperature.

The analyzing the property of the thin film in a state where the substrate is disposed in the chamber may include irradiating or supplying an analysis source to the thin film; and acquiring data corresponding to property of the thin film obtained by the analysis source.

The analysis source may include at least one of an electron beam, an X-ray, and a laser, and the acquiring the data may be configured to use at least one of a fluorescent screen, a camera, and an X-ray detector.

The analyzing the property of the thin film may be configured to use at least any one of scanning electron microscopy (SEM), transmission electron microscopy (TEM), reflection high-energy electron diffraction (RHEED), low-energy electron diffraction (LEED), ellipsometry, and X-ray diffraction (XRD).

In the determining whether the property of the thin film has reached the reference level, when the property of the thin film is determined to be equal to or greater than the reference level, the deposition of the thin film may be terminated.

The thin film deposition method may repeatedly perform the depositing the thin film, the analyzing the property of the thin film, the determining whether the property of the thin film has reached the reference level, the removing the thin film, and the depositing the new thin film until the property of the thin film is equal to or greater than the reference level.

The thin film deposition method may deposit a thin film by using any one of evaporation deposition, metal-organic chemical vapor deposition (MOCVD), molecular beam epitaxy (MBE), pulsed laser deposition (PLD), and sputtering deposition.

The thin film deposition method may be performed by an automated thin film deposition system to which machine learning is applied, and the thin film deposition system may include a substrate holder which is disposed in the chamber, and on which the substrate is placed; a temperature adjust device for controlling a temperature of the substrate placed on the substrate holder; a raw material supply device for supplying a raw material for deposition of the thin film to the substrate placed on the substrate holder; an analysis device for analyzing property of the thin film deposited on the substrate; a removal device configured to remove the thin film from the substrate; and a control device which is connected to the temperature adjust device, the raw material supply device, the analysis device, and the removal device, and comprising a processor capable of processing data obtained from the analysis device and learning a correlation between a process parameter for depositing the thin film and property of the thin film through machine learning.

### Advantageous Effects

According to embodiments of the present invention, in optimizing manufacturing conditions (process conditions) of a thin film such as a two-dimensional material, it is possible to implement an automated thin film deposition system and a thin film deposition method which may easily grow a thin film of high-quality in an automated manner by applying a machine learning method.

When using the automated thin film deposition system and thin film deposition method according to embodiments of the present invention, the optimal (or high-quality) thin film may be efficiently manufactured according to the automation method by utilizing the given material, an analysis device (thin film analysis device), and a removal device (thin film removal device), and the thin film manufacturing process may be optimized without a researcher (developer) being involved in the thin film deposition process each time (one by one), by repeating the process for decomposing/removing a pre-manufactured low-quality thin film in an automated manner in the deposition chamber and for newly depositing a thin film of improved quality under new process conditions through machine learning feedback.

In particular, when using the automated thin film deposition system and thin film deposition method according to embodiments of the present invention, a thin film of low quality is accurately removed from a substrate according to the result of analyzing the thin film, thereby restoring the substrate to an initial state or a state corresponding thereto. In addition, repetitive thin film (material) growth and learning processes may be performed automatically without any manipulations by a researcher (developer) (repeated input and removal of samples, input of measurement results and variable control according to subjective judgment, etc.) in order to obtain a thin film with target property from a given substance and substrate.

An automated thin film deposition system and thin film deposition method according to embodiments of the present invention may be usefully applied not only for a manufacturing a two-dimensional material thin film, but also for growing various nano-materials, semiconductor materials, bio-materials, and so on which may be synthesized and grown physically/chemically with high quality and optimizing the growth conditions.

However, the effects of the present invention are not limited to the above effects, and may be variously extended without departing from the technological spirit and scope of the present invention.

### BRIEF DESCRIPTION OF THE DRAWINGS

FIG. 1 is a diagram illustrating an automated thin film deposition system to which machine learning is applied according to an embodiment of the present invention as an example.

FIG. 2 is a flowchart for explaining, as an example, an automated thin film deposition method to which machine learning is applied according to an embodiment of the present invention. FIG. 3 is a diagram for explaining, as an example, an artificial neural network model of a processor applicable to an automated thin film deposition system and a thin film deposition method to which machine learning is applied according to an embodiment of the present invention.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, element, and/or group thereof and does not exclude the presence or addition of one or more other shapes, steps, numbers, operations, elements, elements and/or groups thereof. In addition, the term, “connection” used in this specification means not only a direct connection of certain members, but also a concept including an indirect connection in which other members are interposed between the members.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and substance tolerances, and exact or absolute figures provided to aid in the understanding of this application are used to prevent the infringers from unfairly exploiting the stated disclosure.

Hereinafter, embodiments of the present invention will be described in detail with reference to the accompanying drawings. A size or a thickness of areas or parts shown in the accompanying drawings may be slightly exaggerated for clarity of the specification and convenience of description. The same reference numbers indicate the same configuring elements throughout the detailed description.

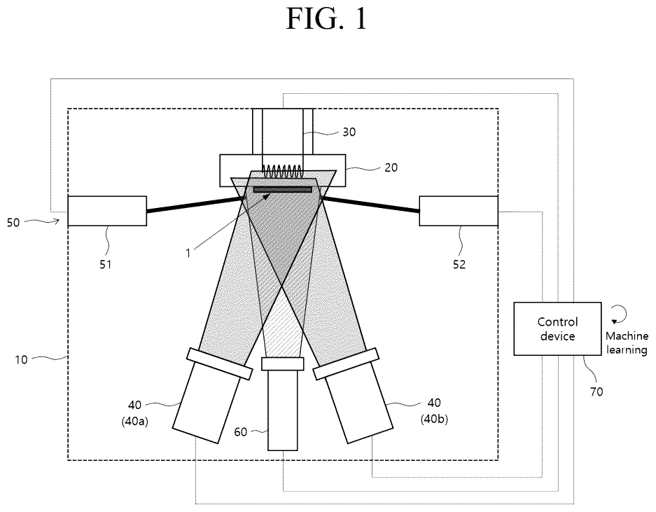

FIG. 1 is a diagram illustrating an automated thin film deposition system to which machine learning is applied according to an embodiment of the present invention as an example.

Referring to FIG. 1, the automated thin film deposition system to which a machine learning is applied (hereinafter, referred to as a thin film deposition system) according to an embodiment of the present invention may include a chamber 10 for depositing a thin film. A raw material (e.g., a precursor material, etc.) of a material to be grown (deposited) may be put into the chamber 10, and a substrate 1 on which a thin film (not shown) may be deposited (grown) may be disposed. The chamber 10 may be a kind of compartment or may have a structure similar to a compartment.

The thin film deposition system may include a substrate holder 20 which is disposed in the chamber 10, and on which the substrate 1 on which the thin film is to be deposited is placed, and a temperature adjust device 30 for controlling a temperature of the substrate 1 placed on the substrate holder 20. The substrate holder 20 may be referred to as a ‘substrate loading unit’. At least a portion of the temperature adjust device 30 may be provided within the substrate holder 20 or placed in contact with the substrate holder 20. The temperature adjust device 30 may serve to maintain the temperature of the substrate 1 at a predetermined temperature during deposition (growth) of the thin film, and when removing a previously manufactured thin film, it may serve to remove the thin film through an evaporation method by heating it to a high temperature. The temperature adjust device 30 may be referred to as a ‘heating device’ or a ‘substrate heating device’.

The thin film deposition system may include a raw material supply device 40 for supplying a raw material for deposition (growth) of the thin film to the substrate 1 disposed on the substrate holder 20. The raw material supply device 40 may be disposed in the chamber 10. The raw material supply device 40 may be provided in singular or plural. In the case of depositing a compound type thin film using a plurality of different raw materials, a plurality of raw material supply devices 40 may be used. Here, although two raw material supply devices 40 are shown, this is an example and the number of raw material supply devices 40 may vary. The reference number 40a may be a first raw material supply device, and the reference number 40b may be a second raw material supply device. The first raw material supply device 40a and the second raw material supply device 40b may be spaced apart from each other and disposed approximately symmetrically with respect to the substrate 1.

The raw material supply device 40 may be, for example, an evaporation device (i.e., an evaporator) capable of supplying the raw material toward the substrate 1 in a gas state or a molecular beam state. In this case, the raw material supply device 40 may be referred to as a raw material evaporation device. However, the raw material supply method of the raw material supply device 40 may be variously changed. For example, the raw material supply device 40 may be configured to supply the raw material in a gaseous state, to supply the raw material in the form of a molecular beam from an effusion cell, or to supply a raw material changed from a target to a gas or plasma state by sputtering the target, or to supply a raw material which is changed from a target to a gas or plasma state by irradiating a laser to the target. In addition, the raw material supply method of the raw material supply device 40 may be variously changed.

The thin film deposition system may include an analysis device 50 for analyzing property (physical properties) of the thin film deposited on the substrate 1. The analysis device 50 may include an analysis source generating unit (analysis source generating part) 51 generating an analysis source (source for analysis) for analyzing the property of the thin film, and an analysis data acquisition unit (analysis data acquisition part) 52 for acquiring data corresponding to the property of the thin film. The data may be derived by the analysis source irradiated or supplied to the thin film. The analysis source is irradiated or supplied to the thin film, the analysis source undergoes a process such as diffraction, reflection, or transmission in the thin film, and then the analysis source that has passed through this process is observed or detected in a predetermined manner, thereby data corresponding to the property of the thin film may be acquired.

For example, the analysis source generating unit 51 may be configured to generate at least one of an electron beam, X-ray, and laser as the analysis source. In addition, the analysis data acquisition unit 52 may be configured to include at least one of a fluorescent screen, a camera, and an X-ray detector. As a specific example, the electron beam is radiated to the thin film, the electron beam passing through the thin film or reflected from the thin film is received and imaged by the fluorescent screen, and then the image is captured by the camera. Thus, the analysis data may be obtained in the form of an image. Alternatively, the X-ray may be irradiated to the thin film, a diffraction pattern of the X-ray by the thin film may be detected by the X-ray detector, and analysis data corresponding thereto-ray may be acquired. However, this is an example, and a specific analysis method of the analysis device 50 may be variously changed.

The analysis device 50 may analyze the property of the deposited thin film without destroying it, and may be used during the deposition process in the deposition chamber 10 or when one batch of deposition is completed. In addition, a method capable of collecting analysis data in the form of an image or a data set may be applied to the analysis device 50. For example, the analysis device 50 may use a method for observing/measuring the surface or crystal structure of the thin film by using an electron microscope such as scanning electron microscopy (SEM) and transmission electron microscopy (TEM), or a method for confirming the crystal structure and crystallinity of the surface of the thin film by electron diffraction methods such as reflection high-energy electron diffraction (RHEED) and low-energy electron diffraction (LEED), a method for detecting the dielectric properties of the surface of the thin film by ellipsometry, and a method for detecting the crystal properties of the thin film by an X-ray diffraction (XRD) method, and the like. In some cases, the analysis device 50 may use at least two of the above methods together. Accordingly, the analysis device 50 may be configured to analyze property of the thin film by using at least one of various analysis methods including SEM, TEM, RHEED, LEED, ellipsometry, and XRD. The analysis device 50 may also be referred to as a ‘property measuring device’.

At least a portion of the analysis source generating unit 51 may be disposed in the chamber 10. For example, all or most of the analysis source generating unit 51 may be disposed in the chamber 10. At least a portion of the analysis data acquisition unit 52 may be disposed in the chamber 10. All or most of the analysis data acquisition unit 52 may be disposed in the chamber 10. In some cases, at least a portion of the analysis data acquisition unit 52 may be disposed outside the chamber 10. The analysis data acquisition unit 52 may be disposed outside the chamber 10 in contact with or adjacent to an outer surface of the chamber 10, and at this time, an outer surface portion (exterior wall portion) of the chamber 10 to which the analysis data acquisition unit 52 contacts or is disposed adjacent to may be a transparent window or transparent.

The thin film deposition system may include a removal device 60 (i.e., thin film removal device) configured to remove the deposited thin film from the substrate 1. For example, the removal device 60 may be configured to generate at least one of plasma, laser, ion beam, and etching gas, and may use at least one of the plasma, laser, ion beam, and etching gas to remove the thin film from the substrate 1 disposed in the chamber 10. The removal device 60 may remove the thin film deposited on the substrate 1 by heating, scraping, or chemically treating the thin film. A low-quality thin film may be easily removed from the chamber 10 by using the removal device 60 in an automated manner.

The thin film deposition system may include a control device 70 connected to the temperature adjust device 30, the raw material supply device 40, the analysis device 50 and the removal device 60. In addition, the control device 70 may be electrically connected to main components (e.g., a pressure controller, a vacuum controller, a gas inlet, a gas outlet, etc.) of the chamber 10. The control device 70 may include a processor capable of processing data obtained from the analysis device 50 and learning a correlation between a process parameter (process variables) for thin film deposition and property (properties) of the thin film by machine learning. The processor may input a process parameter (process variable) to each part of the thin film deposition system, and may process data collected from the analysis device 50 to calculate a correlation between the process parameter and property of the thin film by using a machine learning method.

According to an embodiment of the present invention, the control device 70 may be configured to determine whether the property of the thin film analyzed by the analyzer 50 has reached a given reference level, to remove the thin film from the substrate 1 by using at least one of the removal device 60 and the temperature adjust device 30 when the property of the thin film is less than the reference level, and to deposit a new thin film on the substrate 1 by changing the process parameter.

The thin film deposition system may repeatedly perform the processes for depositing the thin film, analyzing the property of the thin film, determining whether the property of the thin film has reached the reference level, removing the thin film, and depositing a new thin film until the property of the thin film reaches or exceeds the reference level. When it is determined that the property of the thin film analyzed by the analyzer 50 is equal to or greater than the reference level, the control device 70 may terminate the deposition of the thin film. At this time, the control device 70 may operate the thin film deposition system so that the user may take out the substrate 1 and the thin film of high quality formed on the surface thereof. In addition, the control device 70 may provide the user with changes of process parameters and properties of the thin film in the process of repeatedly depositing and removing the thin film.

According to an embodiment of the present invention, during the process of thin film deposition (growth), the thin film deposition system may receive given process parameters (a temperature for preparing raw materials, a substrate temperature, a growth time, a speed, a pressure, and etc.) and may perform a growth process accordingly. As a result, a material (thin film) may be automatically grown on the surface of the substrate 1. Simultaneously with the process, the analysis device 50 (e.g., various analysis devices using electron ray diffraction, X-ray diffraction, electron microscope, etc.) may measure the property of the thin film, and when the result is transmitted from the processor of the control device 70, the property (quality) of the grown thin film (material) may be determined (evaluated) based on the classification and data processing capabilities obtained through machine learning. At this time, if it is determined that the property or quality has reached a desired level, the deposition (growth) of the thin film may be terminated and the user may collect samples (i.e., the substrate and the thin film). And, if it is determined that the property or quality does not reach the desired level, the deposited thin film (material) may be removed by using at least one of the removal device 60 and the temperature adjust device 30 in a state where the substrate 1 is disposed in the chamber 10, so that the substrate 1 may be restored to an initial state or a state corresponding thereto, and a new thin film deposition (growth) may be performed by changing process parameters according to a decision based on data stored in the processor.

Through this process, the user may completely (or almost completely) automatically perform all processes necessary to obtain a thin film of high-quality as intended through one (a series of) process by using the system according to the present embodiment, and the thin film deposition process may be easily and systematically understood in terms of many aspects by constantly collecting and documenting data on the change in property which occur according to the change in process parameters.

The thin film deposition system according to the embodiment of the present invention may be, for example, a two-dimensional material (2D material) or include a two-dimensional material. A two-dimensional material is a single-layer or half-layer solid in which atoms form a predetermined crystal structure. The two-dimensional material may be a conductor, semiconductor or insulator. The two-dimensional material may include, for example, graphene, transition metal chalcogenide (TMD), and hexagonal-boron nitride (h-BN). Here, graphene is a single-layer (monatomic layer) structure in which carbon atoms form a hexagonal structure. The two-dimensional material may have a single-layer structure (2-dimensional planar structure) or a structure in which the single-layer structure (2-dimensional planar structure) is repeatedly stacked. Even if the single-layer structure is repeatedly stacked, the properties of the two-dimensional material may be maintained. In terms of electronic structure, a two-dimensional material may be defined as a material whose density of states (DOS) follows quantum well behavior. Since the density of states (DOS) may follow the quantum well behavior even in a material in which a plurality of two-dimensional unit material layers are stacked (up to about 100 layers), from this point of view, a structure in which the single-layer structure (two-dimensional plane structure) is repeatedly stacked may also be referred to as a ‘two-dimensional material’.

The 2D material may exhibit new and excellent property, which is not observed in general materials, and may play an important role in manufacturing flexible devices, transparent devices, and optical devices, and thus, it is receiving a lot of attention in the fields of semiconductor/electronic devices and optical devices. In order to manufacture devices with excellent performance or to observe new scientific phenomena, a technique for manufacturing a two-dimensional material with excellent crystallinity and high purity is required. A thin film deposition system according to an embodiment of the present invention may be usefully utilized to optimize a process for manufacturing a thin film of a two-dimensional material. In particular, in the case of a two-dimensional material thin film, since it may be easily removed by using the removal device 60 and/or the temperature adjust device 30 without damaging the substrate 1, it may be advantageous to optimize the thin film manufacturing process in an automated manner while maintaining the inherent properties of the substrate 10.

However, in the embodiment of the present invention, the thin film is not limited to a two-dimensional material and may be variously changed. In particular, when the thickness of the thin film is thinned and the type of substrate 1 is appropriately selected, the thin film may be easily removed without damaging the substrate 1, so that the embodiment of the present invention may be applied to materials other than two-dimensional materials. Therefore, the thin film deposition system according to an embodiment of the present invention may be usefully applied when not only for manufacturing a two-dimensional material thin film, but also for growing various nano-materials, semiconductor materials, bio-materials, etc. which may be synthesized and grown physically/chemically with high quality, and optimizing the growth conditions. The above thin film may include various metals, ceramics, bio-materials, and the like. In addition, in the embodiment of the present invention, the thin film may be a single material, but may also be a material having a heterogeneous structure.

Additionally, the substrate 1 used in the embodiment of the present invention may include, for example, silicon Si, silicon germanium SiGe, germanium Ge, silicon carbide SiC, sapphire, etc. The substrate 1 may be a wafer or a wafer piece separated from a wafer. However, the material of the substrate 1 is not limited to the above descriptions and may be variously changed. Before starting thin film deposition, the substrate 1 subjected to appropriate pretreatment may be introduced into the chamber 10 by a user directly or through a mechanized device. The inside of the chamber 10 may be maintained in a vacuum state, for example, and may be designed so that the prepared substrate 1 and the thin film (material) deposited thereon are not deteriorated by oxygen or moisture in the air.

In addition, the thin film deposition system according to an embodiment of the present invention may be configured to deposit thin films by using various deposition methods. For example, the thin film deposition system may be configured to deposit a thin film by using any one of evaporation deposition, metal-organic chemical vapor deposition (MOCVD), molecular beam epitaxy (MBE), pulsed laser deposition (PLD), and sputtering deposition. In the case using MOCVD, the flow rate of gas raw materials supplied for thin film deposition may be adjusted by connecting a mass flow controller (MFC) to the thin film deposition system. In the case using the MBE, the intensity of the raw material beam may be adjusted by connecting a temperature controller of an effusion cell to the thin film deposition system. In the case of using sputtering deposition, process variables such as a thin film deposition rate may be controlled in a computational manner by adjusting a voltage applied to a target raw material. At this time, the control device 70 including the processor in charge of processing and control may be built based on a PC (personal computer) including an interface capable of connecting various devices. In this case, various kinds of devices may be connected to the control device 70 and used without any restrictions on the type or manufacturer of the device to be connected by using a universal communication method such as USB (universal serial bus) or RS-232 (recommended standard-232). Here, evaporation deposition, MOCVD, MBE, PLD, and sputtering deposition have been mainly described, but the thin film deposition system may be configured to use other deposition methods.

In addition, in the embodiment of FIG. 1, a case in which a thin film deposition system is configured in a bottom-up deposition method is illustrated and described, but a thin film deposition system according to an embodiment may be configured in a top-down deposition method or a horizontal deposition method. In addition, the configuration of the thin film deposition system may be variously changed.

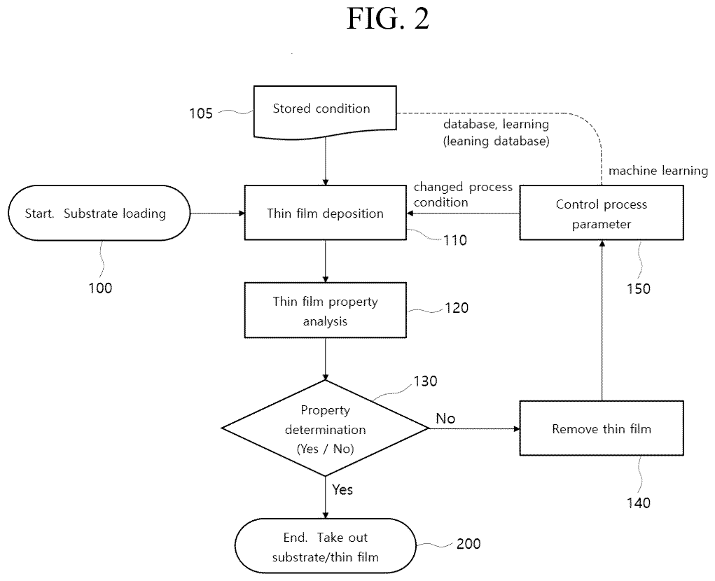

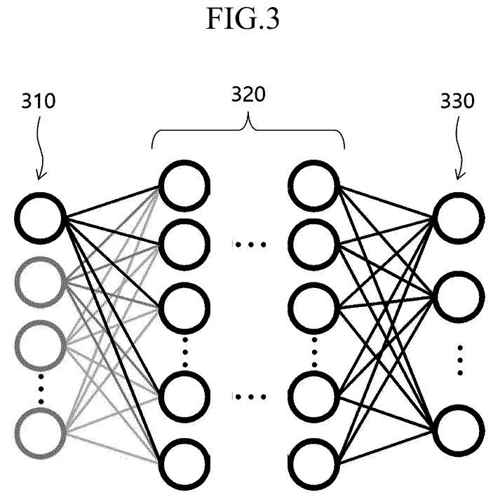

FIG. 2 is a flowchart for explaining, as an example, an automated thin film deposition method to which machine learning is applied according to an embodiment of the present invention. The automated thin film deposition method to which machine learning is applied may be performed by using the automated thin film deposition system described with reference to FIG. 1. Therefore, all of the automated thin film deposition system and related information described in FIG. 1 may be applied to the automated thin film deposition method of FIG. 2.

Referring to FIG. 2, an automated thin film deposition method to which machine learning is applied (hereinafter, referred to as a thin film deposition method) according to an embodiment of the present invention may include starting and substrate loading step 100. At this time, a substrate on which a thin film is to be deposited may be loaded into a chamber for thin film deposition. Before starting thin film deposition, a substrate subjected to appropriate pre-treatment may be introduced into the chamber by a user directly or through a mechanized device. The interior of the chamber may be maintained in a vacuum state, for example, and may be designed so that the prepared substrate and the thin film (material) to be deposited thereon are not deteriorated by oxygen or moisture in the air. The substrate may include, for example, silicon Si, silicon germanium SiGe, germanium Ge, silicon carbide SiC, sapphire, or the like. The substrate may be a wafer or a wafer piece separated from a wafer. However, the material of the substrate is not limited to the above and may be variously changed.

Next, a thin film may be deposited on the substrate disposed in the chamber. This may be referred to as thin film deposition step 110. The first thin film deposition step 110 may be performed according to the condition (preparation method) 105 stored in the thin film deposition system. The stored condition 105 may include various process conditions such as process temperature, flow rate (raw material flow rate), pressure, deposition rate, and time conditions. Here, the stored condition 105 may be an optimal result obtained according to previous learning data or may be set as an initial condition designated by a user. The thin film deposition step 110 may be performed in the chamber 10 described in FIG. 1 by using the temperature adjust device 30, the raw material supply device 40 and so on.

The property of the thin film may be analyzed in a state of the substrate is placed in the chamber. This may be referred to as a property analysis step 120. The property analysis (measurement) may be performed while thin film growth is in progress or after thin film growth is completed. The property analysis step 120 may include irradiating or supplying an analysis source to the thin film and acquiring data corresponding to the property of the thin film obtained by the analysis source. Here, an analysis source may include at least one of an electron beam, an X-ray, and a laser, and the acquiring data may be configured to use at least one of a fluorescent screen, a camera, and an X-ray detector. At this time, the data may have a form of a microscope image or a diffraction pattern, and so on. For example, the property analysis step 120 may be configured to use at least one of scanning electron microscopy (SEM), transmission electron microscopy (TEM), reflection high-energy electron diffraction (RHEED), low-energy electron diffraction (LEED), ellipsometry, and X-ray diffraction (XRD). The property analysis step 120 may be performed by using the analysis device 50 described in FIG. 1, and in connection with the analysis device 50, all contents described in FIG. 1 may be equally applied to FIG. 2.

Then, it may be determined whether the property of the thin film reaches a given reference level. This may be referred to as a property determination step 130. Data acquired in the property analysis step 120 may be transmitted to a processor, and the processor may determine/evaluate the property of the thin film (material) from the obtained data based on previously stored data. The property determination step 130 may be performed by the control device 70 described in FIG. 1.

In the property determination step 130, when the property of the thin film is determined to be less than the reference level, the thin film may be removed from the substrate in a state of the substrate is being placed in the chamber. This may be referred to as a thin film removing step 140. The thin film removing step 140 may include at least one of irradiating or supplying at least one of plasma, laser, ion beam, and etching gas to the thin film and increasing the temperature of the substrate to a critical temperature or higher. In other words, in the thin film removing step 140, the thin film may be removed by using at least one of plasma, laser, ion beam, and etching gas, and/or the thin film may be removed according to a heating process by increasing the temperature of the substrate to a critical temperature or higher. The thin film removing step 140 may be performed by using at least one of the removal device 60 and the temperature adjust device 30 described in FIG. 1. This thin film removing step 140 may be performed within the chamber 10 of FIG. 1.

Next, a process parameter for thin film deposition may be changed by utilizing a machine learning method for learning a correlation between the process parameter for thin film deposition and property of the thin film (step 150), and a new thin film may be deposited on the substrate under a changed process condition (step 110). Based on the difference between the previously grown thin film and a material with target properties, the new process condition obtained by modifying the initially given condition, that is, the stored condition 105, may be transmitted to device units, and a new thin film may be grown. A reference numeral 150 may be referred to as a ‘process parameter control step’, and the thin film deposition step 110 connected to the process parameter control step 150 may be referred to as a ‘new thin film deposition step’. The process parameter control step 150 and the new thin film deposition step 110 may be controlled and performed by the control device 70 described in FIG. 1.

The thin film deposition method may repeatedly and automatically perform the thin film deposition step 110, the property analysis step 120, the property determination step 130, and the thin film removing step 140, the process parameter control step 150, and the new thin film deposition step 110 until the property of the thin film reaches or exceeds the reference level (target level). After removing the deposited low-quality thin film in an appropriate manner in the chamber, and controlling the process parameters (variables) by using a machine learning method, the process for depositing a new thin film may be repeatedly performed (theoretically infinitely repeatable) under the changed process conditions, therefore, it is possible to optimize thin film manufacturing conditions very easily in an automated manner without requiring a user to repeatedly load substrates or manually change process conditions.

In the property determination step 130, when the property of the thin film is determined to be equal to or greater than the reference level, the deposition of the thin film may be terminated (step 200). In the end step 200, the control device (70 in FIG. 1) may operate the thin film deposition system so that the user may take out the substrate and the high-quality thin film formed on the surface thereof. In addition, the control device (70 in FIG. 1) may provide the user with changes in process parameters and properties of the thin film during the process for repeatedly depositing and removing the thin film.

The thin film in the thin film deposition method according to the embodiment of the present invention described above may be, for example, a two-dimensional material or include the same. The thin film deposition method according to an embodiment of the present invention may be usefully used to optimize a process for manufacturing a thin film of a two-dimensional material. In particular, in the case of a two-dimensional material thin film, since it may be easily removed without damaging the substrate, it may be advantageous to optimize the thin film manufacturing process in an automated manner while maintaining the original characteristics of the substrate.

However, in the embodiment of the present invention, the thin film is not limited to a two-dimensional material and may be variously changed. In particular, if the thickness of the thin film is thinned and the type of substrate and the thin film removing method are appropriately selected, the thin film may be easily removed without damaging the substrate, so that the embodiment of the present invention may be applied to materials other than two-dimensional materials. Therefore, the thin film deposition method according to an embodiment of the present invention may be usefully applied when not only in manufacturing a two-dimensional material thin film, but also in growing various nano-materials, semiconductor materials, bio-materials, etc. which may be synthesized and grown physically/chemically with high quality, and optimizing the growth conditions. The above thin film may include various metals, ceramics, bio-materials, and the like.

In addition, the thin film deposition method according to an embodiment of the present invention may be configured to deposit a thin film by using various deposition methods. For example, the thin film deposition method may be configured to deposit a thin film by using any one of evaporation deposition, metal-organic chemical vapor deposition (MOCVD), molecular beam epitaxy (MBE), pulsed laser deposition (PLD), and sputtering deposition. In the case using MOCVD, the flow rate of gas raw materials supplied for thin film deposition may be adjusted by connecting a mass flow controller (MFC) to the thin film deposition system. In the case of using the MBE, the intensity of the raw material beam may be adjusted by connecting a temperature controller of an effusion cell to the thin film deposition system. In the case using sputtering deposition, process variables such as a thin film deposition rate may be controlled in a computational manner by adjusting a voltage applied to a target raw material. Here, evaporation deposition, MOCVD, MBE, PLD, and sputtering deposition have been mainly described, but the thin film deposition method.

FIG. 3 is a diagram for explaining, as an example, an artificial neural network model of a processor applicable to an automated thin film deposition system and a thin film deposition method to which machine learning is applied according to an embodiment of the present invention.

Referring to FIG. 3, a processor which may be applied to a thin film deposition system and a thin film deposition method according to an embodiment of the present invention may learn a correlation between a process parameter for thin film deposition and property of the thin film by using a machine learning method, evaluate the property of the thin film or control the process parameter by using an artificial neural network. The artificial neural network may include an input layer 310, a hidden layer 320, and an output layer 330, and the hidden layer 320 may include a plurality of layers. Process condition data, thin film property data, etc. may be input to the input layer 310, and the evaluation results of thin film properties, the process condition change/control data, etc. may be output through the output layer 330. The artificial neural network may be implemented by using a synapse device, a neuron device, and the like. However, the artificial neural network and its role described with reference to FIG. 3 are only exemplary, and the function and role of the artificial neural network may be expanded in various ways.

According to the embodiments of the present invention described above, when optimizing the manufacturing conditions (process conditions) of a thin film such as a two-dimensional material, it is possible to implement an automated thin film deposition system and a thin film deposition method which may easily grow a thin film of high-quality in an automated manner by applying a machine learning method.

When using the automated thin film deposition system and thin film deposition method according to embodiments of the present invention, the optimal (or high-quality) thin film may be efficiently manufactured according to the automation method by utilizing the given material, an analysis device (thin film analysis device), and a removal device (thin film removal device), and the thin film manufacturing process may be optimized without a researcher (developer) being involved in the thin film deposition process each time (one by one), by repeating the process for decomposing/removing a pre-manufactured low-quality thin film in an automated manner in the deposition chamber and for newly depositing a thin film of improved quality under new process conditions through machine learning feedback.

In particular, when using the automated thin film deposition system and thin film deposition method according to embodiments of the present invention, a thin film of low quality is accurately removed from a substrate according to the result of analyzing the thin film, thereby restoring the substrate to an initial state or a state corresponding thereto. In addition, repetitive thin film (material) growth and learning processes may be performed automatically without any manipulations by a researcher (developer) (repeated input and removal of samples, input of measurement results and variable control according to subjective judgment, etc.) in order to obtain a thin film with target property from a given substance and substrate.

An automated thin film deposition system and thin film deposition method according to embodiments of the present invention may be usefully applied not only for a manufacturing a two-dimensional material thin film, but also for growing various nano-materials, semiconductor materials, bio-materials, and so on which may be synthesized and grown physically/chemically with high quality and optimizing the growth conditions.

According to an embodiment of the present invention, it is possible to implement a control device and process system capable of growing high-quality thin films in an unmanned and automatic manner under optimal conditions by linking process parameters, property measurement, thin film removal, and thin film deposition based on machine learning. Various thin films may be grown with high quality by using the precursor materials and growth devices introduced into the system, and the property of the thin film including the crystal structure may be immediately detected in the same space during the thin film growth process. As the measurement results are analyzed and learned through machine learning, it may be possible to accumulate data corresponding to the growth conditions and results of materials and provide feedback to grow materials with better property. At this time, as the system has the ability to remove the low-quality thin film which has already grown and restore the substrate to its original state through high-energy sources such as laser, plasma, ion beam, heat, and etching gas, the entire processes from inputting a material to obtaining a high-quality thin film may be performed automatically and efficiently at once.

It is expected that the property measurement performed in the same space as the process and supplementary process through machine learning may be widely applied not only to the research stage for manufacturing new types of materials and structures, but also to industries which must manufacture high-performance devices by minimizing the defect rate.

Additionally, in the foregoing description, a control of process parameters (variables) according to a feedback method mainly using machine learning has been described, but in some cases, a feedback method using a method other than machine learning may be applied. Therefore, the thin film deposition system and the thin film deposition method according to embodiments of the present invention may use a feedback method for controlling/changing process parameters by using at least one of various methods including machine learning.

In this specification, the preferred embodiments of the present invention have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with an automated thin film deposition system and thin film deposition method to which machine learning is applied according to the embodiment described with reference to FIGS. 1 to 3, various substitutions, changes, and modifications may be made without departing from the technological spirit of the present invention. Therefore, the scope of the invention should not be determined by the described embodiments, but should be determined by the technological concepts described in the claims.

1. An automated thin film deposition system to which machine learning is applied, comprising:
a substrate holder which is disposed in a chamber for depositing a thin film, and on which the thin film is to be deposited is placed;
a temperature adjust device for controlling a temperature of the substrate placed on the substrate holder;
a raw material supply device for supplying a raw material for deposition of the thin film to the substrate placed on the substrate holder;
an analysis device for analyzing property of the thin film deposited on the substrate;
a removal device configured to remove the thin film from the substrate; and
a control device which is connected to the temperature adjust device, the raw material supply device, the analysis device, and the removal device, and comprising a processor capable of processing data obtained from the analysis device and learning a correlation between a process parameter for depositing the thin film and property of the thin film through machine learning,
wherein the control device is configured to remove the thin film from the substrate by using at least one of the removal device and the temperature adjust device when the property of the thin film analyzed by the analysis device is less than a given reference level, and to deposit a new thin film on the substrate by changing the process parameter.

2. The automated thin film deposition system to which machine learning is applied of claim 1, wherein the thin film includes a two-dimensional material.

3. The automated thin film deposition system to which machine learning is applied of claim 1, wherein the removal device is configured to generate at least one of plasma, laser, ion beam, and etching gas, and to remove the thin film from the substrate disposed in the chamber using at least one of the plasma, laser, ion beam, and etching gas.

4. The automated thin film deposition system to which machine learning is applied of claim 1, wherein the raw material supply device is provided in plurality.

5. The automated thin film deposition system to which machine learning is applied of claim 1, wherein the analysis device comprises:
an analysis source generating unit generating an analysis source for analyzing the property of the thin film; and
an analysis data acquisition unit for acquiring data corresponding to the property of the thin film.

6. The automated thin film deposition system to which machine learning is applied of claim 5,
wherein the analysis source generating unit is configured to generate at least one of an electron beam, an X-ray, and a laser as the analysis source,
wherein the analysis data acquisition unit is configured to include at least one of a fluorescent screen, a camera, and an X-ray detector.

7. The automated thin film deposition system to which machine learning is applied of claim 1, wherein the analysis device is configured to analyze the property of the thin film by using at least one of scanning electron microscopy (SEM), transmission electron microscopy (TEM), reflection high-energy electron diffraction (RHEED), low-energy electron diffraction (LEED), ellipsometry, and X-ray diffraction (XRD).

8. The automated thin film deposition system to which machine learning is applied of claim 1, wherein the control device is configured to terminate the deposition of the thin film when the property of the thin film analyzed by the analysis device is equal to or greater than the reference level.

9. The automated thin film deposition system to which machine learning is applied of claim 1, wherein the thin film deposition system is configured to deposit a thin film by using any one of evaporation deposition, metal-organic chemical vapor deposition (MOCVD), molecular beam epitaxy (MBE), pulsed laser deposition (PLD), and sputtering deposition.

10. An automated thin film deposition method to which machine learning is applied, comprising:
depositing a thin film on a substrate disposed in a chamber for thin film deposition;
analyzing property of the thin film in a state where the substrate is disposed in the chamber;
determining whether the property of the thin film has reached a given reference level;
removing the thin film from the substrate in a state where the substrate is disposed in the chamber when the property of the thin film is determined to be less than the reference level; and
depositing a new thin film on the substrate under a changed process condition by changing a process parameter for thin film deposition using a machine learning method for learning a correlation between a process parameter for thin film deposition and property of the thin film.

11. The automated thin film deposition method to which machine learning is applied of claim 10, wherein the thin film includes a two-dimensional material.

12. The automated thin film deposition method to which machine learning is applied of claim 10, wherein the removing the thin film from the substrate includes at least any one of irradiating or supplying at least one of plasma, laser, ion beam, and etching gas to the thin film; and increasing a temperature of the substrate above a critical temperature.

13. The automated thin film deposition method to which machine learning is applied of claim 10, wherein the analyzing the property of the thin film in a state where the substrate is disposed in the chamber includes irradiating or supplying an analysis source to the thin film; and acquiring data corresponding to property of the thin film obtained by the analysis source.

14. The automated thin film deposition method to which machine learning is applied of claim 13,
wherein the analysis source includes at least one of an electron beam, an X-ray, and a laser,
wherein the acquiring data is configured to use at least one of a fluorescent screen, a camera, and an X-ray detector.

15. The automated thin film deposition method to which machine learning is applied of claim 10, wherein the analyzing the property of the thin film is configured to use at least any one of scanning electron microscopy (SEM), transmission electron microscopy (TEM), reflection high-energy electron diffraction (RHEED), low-energy electron diffraction (LEED), ellipsometry, and X-ray diffraction (XRD).

16. The automated thin film deposition method to which machine learning is applied of claim 10, wherein the deposition of the thin film is terminated when the property of the thin film is determined to be equal to or greater than the reference level in the determining whether the property of the thin film has reached the reference level.

17. The automated thin film deposition method to which machine learning is applied of claim 10, wherein the thin film deposition method repeatedly performs the depositing the thin film, the analyzing the property of the thin film, the determining whether the property of the thin film has reached the reference level, the removing the thin film, and the depositing the new thin film until the property of the thin film is equal to or greater than the reference level.

18. The automated thin film deposition method to which machine learning is applied of claim 10, wherein the thin film deposition method deposits a thin film by using any one of evaporation deposition, metal-organic chemical vapor deposition (MOCVD), molecular beam epitaxy (MBE), pulsed laser deposition (PLD), and sputtering deposition.

19. The automated thin film deposition method to which machine learning is applied of claim 10,
wherein the thin film deposition method is performed by an automated thin film deposition system to which machine learning is applied,
wherein the thin film deposition system comprises:
a substrate holder which is disposed in the chamber, and on which the thin film is to be deposited is placed;
a temperature adjust device for controlling a temperature of the substrate placed on the substrate holder;
a raw material supply device for supplying a raw material for deposition of the thin film to the substrate placed on the substrate holder;
an analysis device for analyzing property of the thin film deposited on the substrate;
a removal device configured to remove the thin film from the substrate; and
a control device which is connected to the temperature adjust device, the raw material supply device, the analysis device, and the removal device, and comprising a processor capable of processing data obtained from the analysis device and learning a correlation between a process parameter for depositing the thin film and property of the thin film through machine learning temperature adjust device temperature adjust device.

20. The automated thin film deposition method to which machine learning is applied of claim 19, wherein the raw material supply device is provided in plurality.
